(19) United States
(12) Patent Application Publication
(10) Pub. No.: US 2024/0206259 A1
(43) Pub. Date: Jun. 20, 2024

(54) Display Device

(71) Applicant: LG Display Co., Ltd., Seoul (KR)

(72) Inventor: Taeyung Kim, Seoul (KR)

(21) Appl. No.: 18/498,544

(22) Filed: Oct. 31, 2023

(30) Foreign Application Priority Data
Dec. 15, 2022 (KR) 10-2022-0175658

(51) Int. Cl. H10K 59/131; H05K 1/02; H05K 1/11; H10K 59/90

(52) U.S. Cl. CPC H10K 59/131; H05K 1/0268; H05K 1/117; H05K 1/118; H10K 59/90; H05K 2201/094; H05K 2201/09409; H05K 2201/10128

(57) ABSTRACT

A display device according to an exemplary embodiment of the present disclosure may comprise a display panel comprising a display area and a non-display area disposed outside the display area, the display panel comprising a plurality of test signal lines and a plurality of first pads disposed in the non-display area; and a flexible circuit board comprising a plurality of second pads and a printed circuit. The plurality of second pads each comprises a body portion and an extension portion. The plurality of first pads is each connected to and overlaps each of the body portions. The plurality of test signal lines is each connected to and overlaps each of the extension portions.

### CROSS-REFERENCE TO RELATED APPLICATION

This application claims the priority of Republic of Korea Patent Application No. 10-2022-0175658 filed on Dec. 15, 2022, in the Korean Intellectual Property Office, which is incorporated by reference in its entirety.

### BACKGROUND

### Field

The present disclosure relates to a display device.

### Description of the Related Art

As the information-oriented society is implemented, there is an increasing user demand for display devices for displaying images. Various types of display devices such as liquid crystal display devices and organic light-emitting display devices are used.

The display device may include a display panel including a display area (or active area) in which a plurality of sub-pixels are disposed, and a non-display area (or non-active area) which is an area disposed outside the display area, and a drive circuit configured to operate the plurality of sub-pixels disposed on the display panel.

The display panel may include a plurality of signal lines that connect the plurality of sub-pixels and the drive circuit. The signal lines may be connected to the drive circuit through pads disposed in the non-display area of the display panel.

For example, data lines through which a data voltage is supplied to the respective sub-pixels are disposed on the display panel. The data lines may be connected to the pads disposed in the non-display area and connected to the drive circuit through the pads.

The pads may be disposed in one row. However, the pads may be disposed in two or more rows as the number of data lines increases to meet a demand for high resolution. In addition, the pads may be disposed in various shapes such as a comb shape or a radial shape to meet a demand for a narrower bezel.

A predetermined gap may be provided between the pads disposed in the non-display area. The pads may be misaligned because of pressure applied during a process of bonding the pad disposed on the display panel and the pad of the drive circuit and because of a material of a substrate positioned below the pad.

In addition, during a process of testing the display panel by applying an auto-prove (AP) signal for testing whether the display panel formed on a mother substrate normally operates and then cutting an outer peripheral portion of a display substrate, some test signal lines are melted by heat and pressure applied by a cutting device, and the melted residue remains on a cut surface of the display panel, which may cause a short circuit between the pads during a process of bonding the pads.

### SUMMARY

An object to be achieved by the present disclosure is to provide a display device capable of reducing misalignment that may occur during a process of bonding a pad disposed on a display panel and a pad of a drive circuit and capable of suppressing a short circuit between lines, in a subsequent pad bonding process, that may occur because of a residue during a process of cutting an outer peripheral portion of a display substrate.

Objects of the present disclosure are not limited to the above-mentioned objects, and other objects, which are not mentioned above, can be clearly understood by those skilled in the art from the following descriptions.

A display device according to an embodiment of the present specification may include: a display panel including a display area and a non-display area that is a region disposed outside the display area, the display panel including a plurality of lines and a plurality of first pads disposed in the non-display area; and a flexible circuit board including a plurality of second pads and a printed circuit, in which the plurality of second pads each includes a body portion and an extension portion, in which the plurality of first pads is each connected to and overlaps each of the body portions, and in which the plurality of lines is each connected to and overlaps each of the extension portions.

According to the embodiment of the present specification, it is possible to reduce misalignment that may occur during the process of bonding the pad disposed on the display panel and the pad of the drive circuit, thereby reducing defective contact between the pads, suppressing a defective operation of the display device, and improving the reliability of the display device.

According to the embodiment of the present specification, it is possible to suppress a short circuit between the lines, during a subsequent pad bonding process, which may be caused by the residue produced during the process of cutting the outer peripheral portion of display substrate, thereby suppressing a defective operation of the display device and improving the reliability of the display device.

According to the embodiment of the present specification, the optimization of the process is implemented in advance in the step of bonding the pads, which makes it possible to save various resources required to repair a defective operation of the display device.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view illustrating a configuration of a display device according to an embodiment of the present specification;

FIG. 2 is a circuit diagram of a configuration of a sub-pixel according to the embodiment of the present specification;

FIG. 3 is a top plan view illustrating a connection relationship between a first pad and a third pad according to the embodiment of the present specification;

FIG. 4 is a cross-sectional view taken along cutting line A-A′ in FIG. 3 according to the embodiment of the present specification;

FIG. 5 is an enlarged view of region A in FIG. 1 according to the embodiment of the present specification;

FIG. 6 is a view illustrating a pad bonding process according to the embodiment of the present specification;

FIG. 7A is a top plan view illustrating a structure made before the first pad and a second pad according to the embodiment of the present specification are bonded;

FIG. 7B is a top plan view illustrating a structure made after the first pad and the second pad according to the embodiment of the present specification are bonded;

FIGS. 8A to 8C are top plan views illustrating structures of pads according to another embodiment of the present specification;

FIG. 9A is a top plan view illustrating a structure made before a first pad and a second pad according to another embodiment of the present specification are bonded;

FIG. 9B is a top plan view illustrating a structure made after the first pad and the second pad according to another embodiment of the present specification are bonded; and

FIGS. 10A to 10C are cross-sectional views taken along cutting line B-B′ in FIG. 9B according to another embodiment of the present specification are bonded.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

In the description of a temporal relationship, for example, when a temporal relationship between two time points is described by using terms “after,” “following,” “next to,” “before,” and the like, the two time points may not be continuous when terms “immediately,” or “directly” is not used.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

In the present specification, the term “display device” may mean a display device in a narrow sense, such as a liquid crystal module (LCM), an organic light-emitting module (OLED Module), or a quantum dot module, that includes a display panel and a drive unit for operating the display panel. Further, the term “display device” may also mean a set electronic apparatus or a set device (or set apparatus) such as a notebook computer, a television, a computer monitor, an automotive display apparatus, an equipment display apparatus including components for a vehicle, a mobile electronic apparatus such as a smartphone or electronic pad that are finished products (complete products or final products) including the LCM, the OLED module, the QD module, and the like.

Therefore, the display device according to the present specification may mean the display device itself, in a narrow sense, such as the LCM, the OLED module, or the QD module, the application product including the LCM, the OLED module, the QD module, and the like, or a set apparatus that is a final consumer device.

Further, in some instances, the LCM, the OLED module, or the QD module, which includes the display panel and the drive unit, may be expressed as the “display device” in a narrow sense. Further, the electronic apparatus, which is the finished product including the LCM, the OLED module, or the QD module, may be expressed as the “set apparatus” that is distinguished from the display device. For example, the display device in a narrow sense includes the display panel, which is a liquid crystal (LCD) display device, an organic light-emitting (OLED) display device, or a quantum dot display device, and a source PCB that is a control unit for operating the display panel. The set apparatus may include a set PCB that is a set control unit electrically connected to the source PCB and configured to control the entire set apparatus.

The display panel used in the present embodiment may be any form of display panel such as a liquid crystal display panel, an organic light emitting diode (OLED) display panel, a quantum dot (QD) display panel, and an electroluminescent display panel. The display panel of the present embodiment is not limited to a particular display panel including a flexible substrate for an organic electroluminescent (OLED) display panel, and a lower backplate support structure and being capable of being subjected to bezel bending. Further, the shapes or sizes of the display panels used for the display device according to the embodiment of the present specification are not limited.

For example, in case that the display panel is an organic electroluminescent (OLED) display panel, the display panel may include a plurality of gate lines (or a gate line), a plurality of data lines (or a data line), and pixels formed in regions in which the gate lines and the data lines intersect. Further, the display panel may include: an array including thin-film transistors that are elements for selectively applying voltages to the respective pixels; and a sealing substrate or sealing layer (encapsulation) disposed on the array to cover an organic light-emitting element (OLED) layer disposed on the array. The sealing layer may protect the thin-film transistor and the organic light-emitting element layer from external impact and inhibit moisture or oxygen from penetrating into the organic light-emitting element layer.

Further, the layer formed on the array may include an inorganic light-emitting layer, for example, a nano-sized material layer or a quantum dot layer.

Hereinafter, there will be described, in detail, embodiments of a display device capable of minimizing misalignment that may occur during a process of bonding a pad disposed on a display panel and a pad of a drive circuit and capable of suppressing a short circuit between lines, in a subsequent pad bonding process, that may occur because of a residue during a process of cutting an outer peripheral portion of a display substrate.

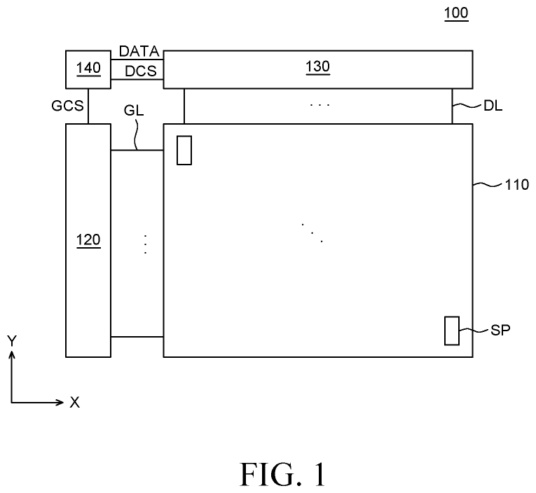

FIG. 1 is a view illustrating a configuration of a display device according to an embodiment of the present specification.

With reference to FIG. 1, a display device 100 according to an embodiment of the present specification may include: a display panel 110 on which a plurality of gate lines GL, a plurality of data lines DL, and a plurality of sub-pixels SP are disposed; a gate drive circuit 120 connected to the plurality of gate lines GL; a data drive circuit 130 connected to the plurality of data lines DL; and a controller 140 configured to control the gate drive circuit 120 and the data drive circuit 130.

The display panel 110 may include: a display area (active area, AA) in which the plurality of sub-pixels SP for displaying images is disposed and a non-display area (non-active area, NA) positioned in an area disposed outside the display area AA.

The gate drive circuit 120 may output scan signals to the plurality of gate lines GL and control drive timing of the sub-pixels SP disposed on the display panel 110.

The gate drive circuit 120 may sequentially operate the plurality of gate lines GL by sequentially supplying on-voltage scan signals or off-voltage scan signals to the plurality of gate lines GL under the control of the controller 140.

The gate drive circuit 120 may be positioned at one side of the display panel 110 or at two opposite sides of the display panel 110 depending on driving methods. The gate drive circuit 120 may include one or more gate driver integrated circuits GD-IC.

The gate driver integrated circuits GD-IC may be disposed at various positions. For example, the gate driver integrated circuits GD-IC may each be connected to a bonding pad (panel pad) of the display panel 110 on at least one side of the display panel 110 by tape automated bonding (TAB). For example, the gate driver integrated circuits GD-IC may each be implemented as a gate-in-panel (GIP) type by a chip-on-glass (COG) method and disposed directly on the display panel 110. However, the present specification is not limited thereto.

For example, the gate driver integrated circuits GD-IC may each be implemented by a chip-on-film (COF) method in which the gate driver integrated circuit is mounted on a film on which the display panel 110 and the gate drive circuit 120 are connected. However, the present specification is not limited thereto.

The data drive circuit 130 outputs a data voltage to the data line DL in accordance with the timing of applying the scan signal through the gate line GL, thereby allowing each of the sub-pixels SP to express brightness in accordance with image data.

When a particular gate line GL is opened, the data drive circuit 130 converts image data, which are received from the controller 140, into an analog data voltage and supplies the analog data voltage to the plurality of data lines DL, thereby operating the plurality of data lines DL.

The data drive circuit 130 may include one or more source driver integrated circuits SD-IC and operate the plurality of data lines DL.

The source driver integrated circuits SD-IC may be disposed at various positions. For example, the source driver integrated circuits SD-IC may each be connected to the bonding pad (panel pad) of the display panel 110 at one side of the display panel 110 by tape automated bonding (TAB). For example, the source driver integrated circuits SD-IC may be disposed by being integrated with the display panel 110. However, the present specification is not limited thereto.

For example, the source driver integrated circuits SD-IC may each be implemented by a chip-on-film (COF) method in which the source driver integrated circuit is mounted on a film on which the display panel 110 and the data drive circuit 130 are connected. In this case, one side of the source driver integrated circuit SD-IC may be bonded to at least one source printed circuit board S-PCB, and the other side of the source driver integrated circuit SD-IC may be bonded to the display panel 110.

The controller 140 supplies various types of control signals to the gate drive circuit 120 and the data drive circuit 130 and controls an operation of the gate drive circuit 120 and an operation of the data drive circuit 130.

The controller 140 may start scanning in accordance with the timing implemented

for each frame. The controller 140 may convert input image data (or external data) received from the outside into data suitable for a data signal format used for the data drive circuit 130 and output the converted image data DATA. The controller 140 may control data driving at the proper time in accordance with the scanning.

The controller 140 may receive various types of timing signals including a vertical synchronizing signal Vsync, a horizontal synchronizing signal Hsync, an input data enable signal DE, a clock signal CLK, and the like together with the input image data from the outside (e.g., a host system).

The controller 140 may convert the input image data received from the outside into the data suitable for the data signal format used for the data drive circuit 130 and output the converted image data DATA. Further, the controller 140 may generate various types of control signals by using a timing signal received to control the gate drive circuit 120 and the data drive circuit 130 and output the control signals to the gate drive circuit 120 and the data drive circuit 130.

For example, to control the gate drive circuit 120, the controller 140 may output various types of gate control signals GCS including a gate start pulse GSP, a gate shift clock GSC, a gate output enable signal GOE, and the like.

For example, the gate start pulse GSP may control the operation start timing of the one or more gate driver integrated circuits GD-IC that constitute the gate drive circuit 120. For example, the gate shift clock GSC is a clock signal inputted in common to the one or more gate driver integrated circuits GD-IC and may control shift timing of the scan signal. For example, the gate output enable signal GOE may designate timing information of the one or more gate driver integrated circuits GD-IC.

To control the data drive circuit 130, the controller 140 may output various types of data control signals DCS including a source start pulse SSP, a source sampling clock SSC, a source output enable signal SOE, and the like.

For example, the source start pulse SSP may control data sampling start timing of the one or more source driver integrated circuits SD-IC that constitute the data drive circuit 130. For example, the source sampling clock SSC may be a clock signal for controlling sampling timing of the data in each of the source driver integrated circuits SD-IC. For example, the source output enable signal SOE may control output timing of the data drive circuit 130.

The controller 140 may be disposed on a control printed circuit board C-PCB. The control printed circuit board C-PCB may be connected to the source printed circuit board S-PCB by means of a connection medium such as a flexible flat cable FFC or a flexible printed circuit FPC. However, the present specification is not limited thereto.

A power controller may be disposed on the control printed circuit board C-PCB. The power controller may supply various types of voltages or currents to the display panel 110, the gate drive circuit 120, the data drive circuit 130, and the like or control various types of power or current to be supplied.

A signal line disposed on the display panel 110 may be connected to a pad or a panel pad of the display panel 110 and connected to the drive circuit through the pad or the panel pad.

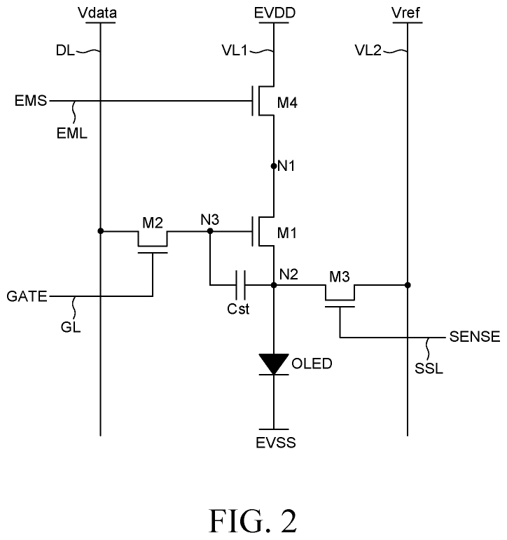

FIG. 2 is a circuit diagram of a configuration of a sub-pixel according to the embodiment of the present specification.

With reference to FIG. 2, the sub-pixel (or pixel) SP may include a first transistor M1, a second transistor M2, a third transistor M3, a storage capacitor Cst, and a light-emitting diode OLED.

A first electrode of the first transistor M1 may be connected to a first node N1 that is connected to a first power line VL1 to which first power EVDD is transmitted. A second electrode of the first transistor M1 may be connected to a second node N2. A gate electrode of the first transistor M1 may be connected to a third node N3. The first transistor M1 may allow a drive current, which is generated by the first power EVDD supplied to the first node N1 in response to a voltage transmitted to the gate electrode, to flow to the second electrode.

A first electrode of the second transistor M2 may be connected to a data line DL that transmits a data voltage Vdata. A second electrode of the second transistor M2 may be connected to the third node N3. A gate electrode of the second transistor M2 may be connected to the gate line GL that supplies a gate signal. The second transistor M2 may receive the gate signal and supply a data voltage Vdata, which is to be transmitted to the data line DL, to the gate electrode of the first transistor M1. The gate signal may be supplied from the gate drive circuit 120 illustrated in FIG. 1.

A first electrode of the third transistor M3 may be connected to a second power line VL2 that transmits a reference voltage Vref. A second electrode of the third transistor M3 may be connected to the second node N2. A gate electrode of the third transistor M3 may be connected to a sensing line SSL. The third transistor M3 may receive a sensing signal SENSE and apply the reference voltage Vref, which is to be transmitted to the second power line VL2, to the second electrode of the first transistor M1. The second node N2 may be initialized by the reference voltage Vref. The sensing signal SENSE may be supplied from the gate drive circuit 130 illustrated in FIG. 1. The data signal may be supplied from the data drive circuit 130 illustrated in FIG. 1.

A first electrode of the storage capacitor Cst may be connected to the third node N3, and a second electrode of the storage capacitor Cst may be connected to the second node N2. The storage capacitor Cst may be disposed between the gate electrode of the first transistor M1 and the second electrode of the first transistor M1 and maintain a voltage difference between the gate electrode of the first transistor M1 and the second electrode of the first transistor M1.

An anode electrode of the light-emitting diode OLED may be connected to the second node N2, and a cathode electrode of the light-emitting diode OLED may be connected to second power EVSS. A voltage level of the second power EVSS may be lower than a voltage level of the first power EVDD. The light-emitting diode OLED may emit light in response to a current flowing in a direction from the anode electrode to the cathode electrode. The light-emitting diode OLED may include a light-emitting layer that emits light by a current flowing between the anode electrode and the cathode electrode. The light-emitting layer may be an organic material layer. However, the embodiments of the present specification are not limited thereto.

In the sub-pixel SP configured as described above, the first transistor M1 and the second transistor M2 may each be an NMOS transistor, and the third transistor M3 may be a PMOS transistor. However, the present specification is not limited thereto. The first electrode and the second electrode of each of the first, second, and third transistors M1, M2, and M3 may be a drain electrode and a source electrode, respectively. However, the present specification is not limited thereto.

The drive current supplied from the first transistor M1 may flow in accordance with Equation 1 below.

Id=k(Vgs−Vth)² [Equation 1]

In this case, Id may represent the amount of drive current supplied from the first transistor M1, Vgs may represent a difference in voltage between the gate electrode and the source electrode of the first transistor M1, and Vth may represent a threshold voltage of the first transistor M1. In addition, k may represent mobility.

With reference to Equation 1, the drive current corresponds to a difference in voltage between the gate electrode and the source electrode of the first transistor M1. Therefore, in case that the second electrode is the source electrode, the drive current may flow in response to the data signal when the data voltage Vdata corresponding to the data signal is transmitted to the source electrode, and the reference voltage Vref is transmitted to the gate electrode.

The sub-pixel SP may include a fourth transistor M4. A first electrode of the fourth transistor M4 may be connected to the first power line VL1 that supplies the first power EVDD. A second electrode of the fourth transistor M4 may be connected to the first node N1. In addition, a gate electrode of the fourth transistor M4 may be connected to a light-emitting control signal line EML that transmits a light-emitting control signal EMS.

The light-emitting control signal line EML may be connected to the gate drive circuit 120 illustrated in FIG. 1 and supplied with the light-emitting control signal from the gate drive circuit 120.

When the fourth transistor M4 is turned on by the light-emitting control signal, the fourth transistor M4 may apply the voltage of the first power EVDD to the first node N1. The fourth transistor M4 may be an NMOS transistor. However, the present specification is not limited thereto.

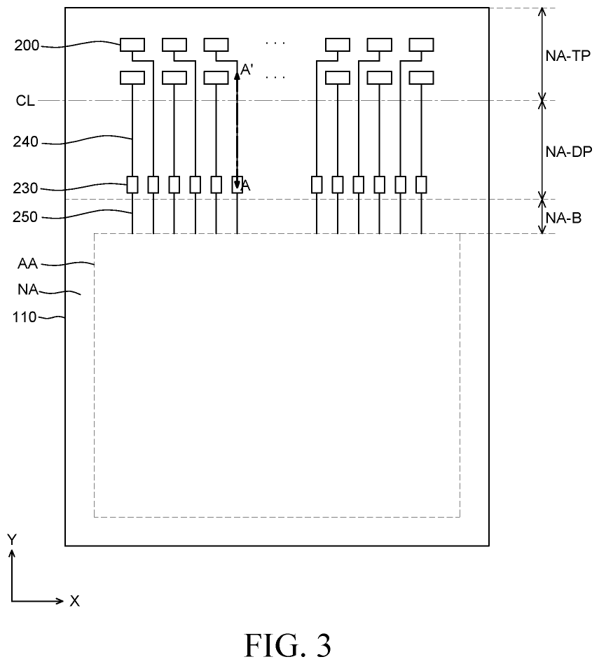

FIG. 3 is a top plan view illustrating a connection relationship between a first pad and a third pad according to the embodiment of the present specification.

With reference to FIG. 3, the display panel 110 of the display device 100 according to the embodiment of the present specification may include the display area AA and the non-display area NA. The non-display area NA may include a bending area NA-B, a display pad area NA-DP, a test pad area NA-TP, and the like.

The display area AA may display an image. In the display area AA, a plurality of pixels (or sub-pixels) SP may be disposed, a plurality of data lines (DL in FIGS. 1 and 2) configured to apply data signals and gate signals to the respective pixels SP may be disposed, and a plurality of gate lines (GL in FIGS. 1 and 2) may be disposed. The lines disposed in the display area AA are not limited to the data line DL and the gate line GL.

The non-display area NA may be disposed adjacent to an outer peripheral region of the display area AA. The non-display area NA may include: the display pad area NA-DP in which a plurality of display pads (or first pads) 230 are disposed; and the bending area NA-B in which a plurality of connection lines (or second lines) 250 are disposed and connects the plurality of display pads (or first pad) 230 disposed in the display pad area NA-DP to lines disposed in the display area AA or the non-display area NA. For example, the plurality of display pads 230 may be the first pads. However, the embodiments of the present specification are not limited thereto.

The display pad area NA-DP may be disposed in the non-display area NA disposed at one side of the display area AA. The display pad area NA-DP may include the plurality of first pads (or display pads) 230. A driver IC may be connected or fastened to the plurality of first pads 230.

The bending area NA-B may be disposed between the display area AA and the display pad area NA-DP. The bending area NA-B may be curved or bent in the non-display area NA of the display panel 110. For example, in the bending area NA-B, the display pad area NA-DP may be disposed to be curved toward a rear surface of the display area AA. When the display pad area NA-DP is disposed on the rear surface of the display area AA, an area of the display area AA, which can be visible from a front surface of the display area AA, may increase, and an area of the non-display area NA may decrease in comparison with the display device 100 in which the display pad area NA-DP is disposed on the front surface of the display area AA. Therefore, it is possible to implement a narrow bezel.

The plurality of connection lines (or second lines) 250 may be disposed in the bending area NA-B. The plurality of connection lines (or second lines) 250 may connect the lines disposed in the display area AA to the first pads 230 in the non-display area NA.

However, the embodiments of the present specification are not limited thereto. For example, the second line (or connection line) 250 may connect the first pads 230 to the lines disposed in the non-display areas NA disposed at two opposite sides of the display area AA.

A plurality of test pads (or third pads) 200 may be disposed in the test pad area NA-TP. Test signals applied to the plurality of test pads 200 may be transmitted to the plurality of first pads 230 disposed in the display pad area NA-DP through test signal lines (or first lines) 240. For example, the plurality of test pads 200 may be the third pads. However, the embodiments of the present specification are not limited thereto. For example, the test signal line 400 may be the first line or a first signal line. However, the embodiments of the present specification are not limited thereto.

When the test on the display device 100 is completed, the test pad area NA-TP may be removed from the display panel 110 by a cutting process. For example, when the test on the display device 100 is completed, the display panel 110 may be cut along a predetermined cutting line CL between the test pad (or third pad) 200 and the first pad 230. Therefore, the test pad area NA-TP may be removed from the display panel 110.

The cutting process may be performed by using heat generated from a laser or using a frictional force generated by a scriber. During the cutting process, high-temperature heat and high pressure may be applied to the cutting line CL and two opposite sides of the display panel 110 based on the cutting line CL.

Some of the plurality of first lines (or test signal lines) 240 may be cut during the process of cutting the display panel 110. For example, at the time of cutting the display panel 110 along the predetermined cutting line CL between the third pad (or test pad) 200 and the first pad (or display pad) 230, the first line 240 disposed between the third pad 200 and the first pad 230 may also be cut.

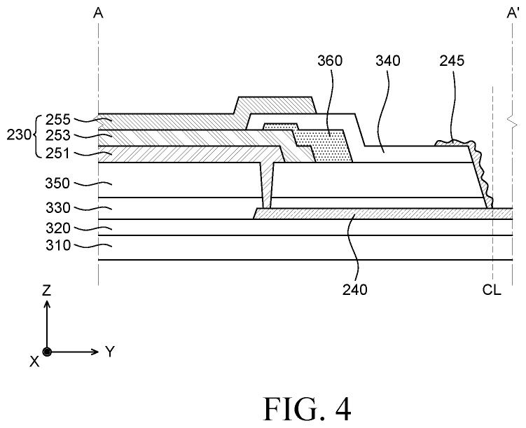

FIG. 4 is a cross-sectional view taken along cutting line A-A′ in FIG. 3 according to one embodiment.

With reference to FIG. 4, one side of the display panel 110 of the display device 100 according to the embodiment of the present specification based on cutting line A-A′ may include a structure or a layered structure including a substrate 310, a gate insulation layer 320, a first interlayer insulation layer 330, a buffer layer 350, a second interlayer insulation layer 340, and a planarization layer 360. The first pad 230 and the first line (or test signal line) 240 may be included in the structure or the layered structure of the display panel 110.

The display panel 110 may include the substrate 310. The display panel 110 may include the display area AA and the non-display area NA. For example, the non-display area NA may be an area disposed outside the display area AA. For example, the non-display area NA may be disposed in an area disposed outside the display area AA. The plurality of first pads 230 and the plurality of first lines 240 may be disposed in the non-display area NA of the substrate 310.

The display panel 110 may include the substrate 310, and the signal lines such as the plurality of data lines DL and the plurality of gate lines GL disposed on the substrate 310. The display panel 110 may include the plurality of sub-pixels SP connected to the plurality of data lines DL and the plurality of gate lines GL.

The gate insulation layer 320, the first interlayer insulation layer 330, the buffer layer 350, the second interlayer insulation layer 340, and the planarization layer 360 may be configured on the substrate 310. The gate insulation layer 320 may be formed on the entire surface of the substrate 310 to insulate the gate electrodes and active layer patterns (or semiconductor layers or semiconductor layer patterns) of various transistors disposed on the substrate 310.

The first interlayer insulation layer 330, the buffer layer 350, the second interlayer insulation layer 340, and the planarization layer 360 may each be formed on the entirety or a part of the surface of the substrate 310 to insulate various electrodes or various lines formed on upper and lower portions thereof. In addition, the buffer layer 350 and the planarization layer 360 may each be formed to flatten the substrate by eliminating level differences caused by various electrodes or various lines disposed on the lower portions of the buffer layer 350 and the planarization layer 360.

With reference to FIG. 4, the first pad 230 may include one or more layers. For example, the first pad 230 may include a first electrode 251, a second electrode 253, and a third electrode 255 disposed on the buffer layer 350. However, the present specification is not limited thereto. For example, the first pad 230 may include the first electrode 251, the second electrode 253, and the third electrode 255 stacked on the buffer layer 350. However, the present specification is not limited thereto.

The first electrode 251 and the first line 240 may be disposed in different layers. For example, the first interlayer insulation layer 330 and the buffer layer 350 may be connected to the first line 240 through contact holes in the first interlayer insulation layer 330 and the buffer layer 350. However, the present specification is not limited thereto. For example, the first electrode 251 and the first line 240 may be formed in the same layer. For example, the first line 240 and the third electrode 255 may be formed in the same layer. Hereinafter, for convenience, the embodiment will be described in which the first line 240 and the third electrode 255 are formed in the same layer. However, the embodiments of the present specification are not limited thereto.

The second pad may be disposed on an upper portion of the third electrode 255. The third electrode 255 may be electrically connected to the second pad. For example, the third electrode 255 and the second pad are electrically connected by a conductive film (anisotropic conductive film (ACF)) disposed between the third electrode 255 and the second pad.

The second electrode 253 may be disposed between the first electrode 251 and the third electrode 255. The second electrode 253 may be made of a material excellent in electrical conduction efficiency.

In the non-display area NA, the plurality of first lines 240 may each connect each of the plurality of first pads (or panel pads) 230 and each of the plurality of third pads (or test pads) 200. A width of each of the first lines 240 may be smaller than a width of each of the first pads 230. For example, a distance between the first lines 240 may be longer than a distance between the first pads 230.

The first line 240 may be cut together with the display panel 110 during the process of cutting the display panel 110. For example, one side of the first line 240 may be exposed to the cut outer peripheral portion (or cross-section) of the display panel 110.

One side of each of the plurality of first lines 240 may extend in a direction of the display area AA and be connected to one side of each of the plurality of first pads 230. The other side of each of the plurality of first lines 240 may extend in a direction of a flexible circuit board F-PCB and be connected to the outer peripheral portion of the display panel 110.

During the process of cutting the first line 240, a residue 245 of the first line 240 may be produced by high-temperature heat and high pressure generated during the process of cutting the display panel 110. For example, debris of the first line 240 and a molten material of the debris, which are produced by high-temperature heat and high pressure may remain on a cross-section of the display panel 110 and a cross-section and a peripheral portion of the first line 240 exposed to the cross-section of the display panel 110.

The residue 245 of the first line 240 may be disposed over some of the plurality of first lines 240. For example, the residue 245 may be disposed between the plurality of first lines 240 and define electrical connection between some of the plurality of first lines 240.

In addition, the residue 245 of the first line 240 may be disposed in a flat area between the plurality of first lines 240. For example, the residue 245 may be disposed between the plurality of first lines 240 without defining electrical connection between the first lines 240. The residue 245 disposed between the plurality of first lines 240 may define electrical connection between some of a plurality of second pads 500 during a subsequent process of bonding the first pad 230 and the second pad (or film pad) 500.

The electrical connection defined between some of the plurality of first lines 240 or between some of the plurality of second pads 500 by the residue 245 may cause an erroneous operation of the display panel 110, which may cause a problem with reliability of the display device 100. For example, an inherent data voltage (or data voltage) according to an image applied to the data line DL may cause an erroneous operation of the display panel 110 because of the electrical connection between the data lines DL defined by the residue.

To reduce an influence caused by the residue 245, the width of each of the first lines 240 may be smaller than the width of each of the first pads 230. For example, the width of each of the first lines 240 may vary depending on a disposition position or a shape of the residue 245.

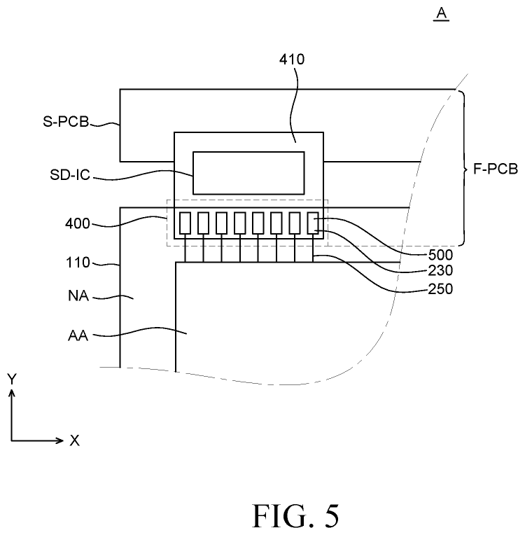

FIG. 5 is an enlarged view of region A in FIG. 1, i.e., a top plan view illustrating a connection relationship between the first pad and the second pad according to one embodiment.

With reference to FIG. 5, in the display device 100 according to the embodiment of the present specification, the first pad 230 disposed on a top surface of one side of the non-display area NA of the display panel 110 may be bonded to the flexible printed circuit board F-PCB in a bonding part 400.

The flexible printed circuit board (or flexible circuit board) F-PCB may include the source printed circuit board S-PCB and a film circuit board 410. The source driver integrated circuit SD-IC may be mounted on the film circuit board 410 by a COF method. The second pad (or film pad) 500 may be disposed on a rear surface of one side of the film circuit board 410.

A conductive film ACF, which contains conductive balls and a bonding agent, may be disposed between the first pad 230 of the display panel 110 and the second pad 500 of the film circuit board 410 that adjoin each other in the bonding part 400. In the bonding process, the first pad 230, the conductive film ACF, and the second pad 500 may be compressed by instantaneously applied heat and pressure in the bonding part 400.

As the bonding agent is melted, the conductive balls contained in the compressed conductive film ACF may electrically connect the first pad 230 and the second pad 500. As the bonding agent is cured, the first pad 230, the conductive balls, and the second pad 500 are kept electrically connected.

The first pad 230 of the display panel 110 may have a rectangular shape. However, the present specification is not limited thereto. As the non-display area NA of the display device 100 decreases, the first pad 230 may be shaped so that the first pad 230 occupies a small portion of the non-display area NA. For example, the first pad 230 may have a parallelogrammatic shape to decrease a height of the bonding part 400. The first pad 230 may have a parallelogrammatic shape, a rhombic shape, a comb shape, a radial shape, or the like. However, the present specification is not limited to the term.

The shape of each of the plurality of first pads 230 may vary depending on a disposition position. For example, the first pad 230, which is positioned at one side of the display panel 110, and the first pad 230, which is positioned at the other side, may have a symmetric shape or an inverted shape. For example, the first pad 230 positioned at one side of the display panel 110 may have a “ \ ” shape, and the first pad 230 positioned at the other side of the display panel 110 may have a “/” shape.

The shape of the second pad 500 may vary depending on the shape of the first pad 230. The first pad 230 and the second pad 500 may have the same shape. However, the present specification is not limited thereto.

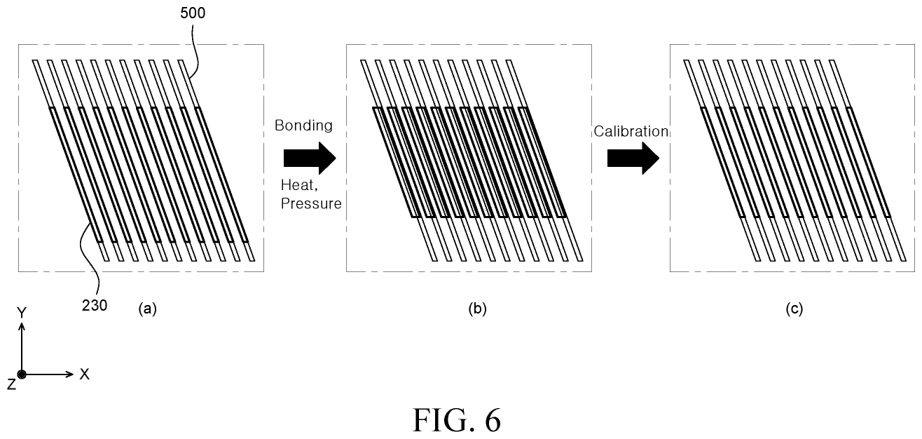

FIG. 6 is a view illustrating a pad bonding process according to the embodiment of the present specification.

With reference to part (a) of FIG. 6, the first pad 230 may be disposed at a lower side, and the second pad 500 may be disposed at an upper side. However, the present specification is not limited thereto. The conductive film ACF may be disposed between the first pad 230 and the second pad 500.

The first pad 230 and the second pad 500 may each have a parallelogrammatic shape. However, the present specification is not limited thereto. In consideration of an error in a longitudinal direction during the bonding (or joining) process, a length (or area) of the second pad 500 may be longer than a length (or area) of the first pad 230. However, the present specification is not limited thereto. For example, after the bonding process, the first pad 230 may have a region that is not joined to the second pad 500.

During the bonding process, heat and pressure may be applied to the first pad 230 in a direction (or Z direction) from the rear surface to the top surface. Heat and pressure may be applied to the second pad 500 in a direction (or-Z direction) from the top surface to the rear surface.

As the bonding agent is melted, the conductive balls contained in the compressed conductive film ACF may electrically connect the first pad 230 and the second pad 500. As the bonding agent is cured, the first pad 230, the conductive balls, and the second pad 500 are kept electrically connected.

With reference to part (b) of FIG. 6, misalignment may occur between the first pad 230 and the second pad 500 that are bonded. The misalignment may be caused by the temperature and application time of compression heat, the intensity and direction of compression pressure, and the like. However, the present specification is not limited thereto. For example, the misalignment may be caused by the configurations, shapes, and materials of the first pad 230 and the second pad 500, the configurations and hardness of the display panel 110 and the film circuit board 410, the ambience of the bonding process, and the like.

A degree of misalignment may be measured on the basis of the area and direction between the pads to be bonded. However, the present specification is not limited thereto. In case that a degree of the misalignment is measured on the basis of the area, the degree of the misalignment may be measured on the basis of a ratio of an area in which the first pad 230 and the second pad 500 are joined to overlap each other with respect to an area of the first pad 230. The area in which the first pad 230 and the second pad 500 overlap each other may be a conductive area. For example, the number of conductive balls in a conductive film 550 disposed in the area in which the first pad 230 and the second pad 500 are joined may also be measured.

A direction of the misalignment between the first pad 230 and the second pad 500 may be disposed at one side or the other side of the first pad 230 so that the second pad 500 is parallel to the first pad 230 on the basis of the first pad 230. However, the present specification is not limited thereto. For example, the direction of the misalignment may be disposed so that the second pad 500 and the first pad 230 intersect each other without being parallel to each other.

The misalignment between the first pad 230 and the second pad 500 may have the same aspect for each batch (or work) unit (lot) of the bonding process. For example, the misalignment that occurs in an initial process may be repeated consistently throughout the process. It may be necessary to calibrate the process at an initial stage of the process to suppress misalignment.

An offset method of changing a relative position of the second pad 500 with respect to a position of the first pad 230 may be used to correct the misalignment between the first pad 230 and the second pad 500. However, the present specification is not limited thereto. The offset method may correct the misalignment by changing a relative position by an equal distance in a direction opposite to the direction and distance in which the misalignment between the first pad 230 and the second pad 500 that are disposed in parallel.

With reference to part (c) of FIG. 6, the misalignment between the first pad 230 and the second pad 500 may be corrected by the offset method. In the corrected disposition, the first pad 230 and the second pad 500 may be aligned, such that the first pad 230 and the second pad 500 may be disposed to overlap each other.

With reference to FIG. 6, the example has been described in which the first pad 230 and the second pad 500 are disposed in one row. However, the present specification is not limited thereto. For example, the first pad 230 and the second pad 500 may be disposed in a plurality of rows.

With reference to FIG. 6, the example has been described in which the first pad 230 and the second pad 500 each have a parallelogrammatic shape. However, the present specification is not limited thereto. For example, the first pad 230 and the second pad 500 may each have a triangular shape, a rectangular shape, a rhombic shape (or diamond shape), and the like. Hereinafter, for convenience, the embodiment will be described in which the first pad 230 and the second pad 500 each have a rectangular shape.

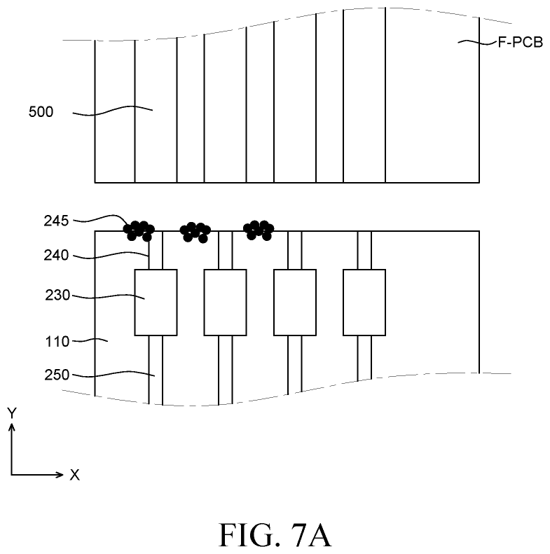

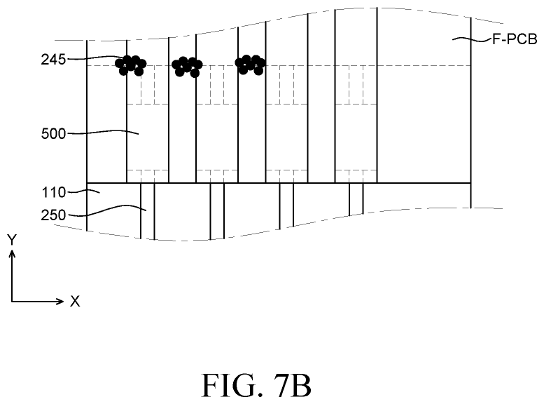

FIG. 7A is a top plan view illustrating a structure made before the first pad and the second pad according to the embodiment of the present specification are bonded.

FIG. 7B is a top plan view illustrating a structure made after the first pad and the second pad according to the embodiment of the present specification are bonded.

With reference to FIGS. 7A and 7B, the first pad 230, the second line 250, and the first line 240 may be disposed at the upper side of the display panel 110, and the second pad 500 may be disposed on the rear surface of the flexible circuit board F-PCB.

With reference to FIGS. 4, 7A, and 7B, the disposition position of the first line 240 may be positioned on the gate insulation layer 320 or positioned on the same layer as the third electrode 255. However, the present specification is not limited thereto. For example, the first line 240 may be disposed between constituent element layers between the substrate 310 and the third electrode 255.

In case that the first line 240 and the third electrode 255 are positioned on the same layer, the first line 240 and the first pad 230 may be exposed together to the top surface of the display panel 110 during the bonding process. In case that the first line 240 is disposed between constituent element layers other than the third electrode 255, the first line 240 may be exposed to a cross-sectional portion of the display panel 110 during the bonding process. The residue 245, which is produced during the cutting process, may be disposed on one side portion and the cross-sectional portion of the display panel 110.

With reference to FIG. 7B, when the bonding process is completed, the first pad 230 of the display panel 110 and the second pad 500 of the flexible circuit board F-PCB may be joined (or bonded). The first pad 230 and the second pad 500 may be joined directly to each other without an interlayer material. However, the present specification is not limited thereto. For example, the conductive film ACF containing the conductive balls may be disposed between the first pad 230 and the second pad 500.

With reference to FIG. 7B, when the bonding process is completed, the residue 245 disposed on one side portion and the cross-sectional portion of the display panel 110 may come into contact with a partial region of the second pad 500 of the rear surface of the flexible circuit board F-PCB. For example, the residue 245 may connect some of the plurality of second pads 500, which may cause a short circuit between the connected pads among the plurality of second pads 500. For this reason, a signal applied to the display panel 110 erroneously operates, which may cause a defect of the display device 100.

In addition, the residue 245 is disposed on one side portion and a short side portion of the display panel 110 and connects some of the plurality of first lines 240, which may cause a short circuit between the connected lines among the plurality of first lines 240. The plurality of first pads 230 connected to the short-circuited line may also be short-circuited. For this reason, an electrical signal applied to the display panel 110 erroneously operates, which may cause a defect of the display device 100.

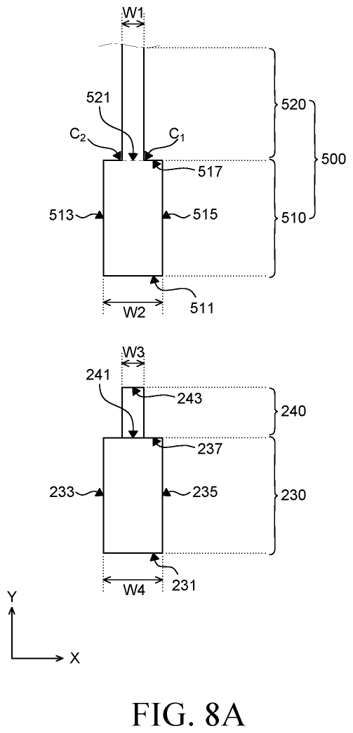

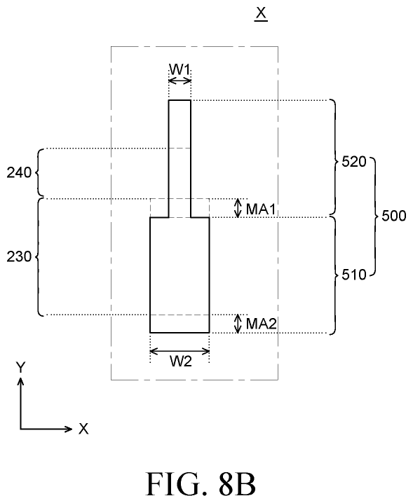

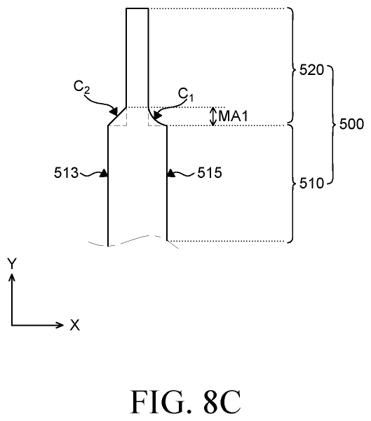

FIGS. 8A to 8C are top plan views illustrating structures of pads according to another embodiment of the present specification.

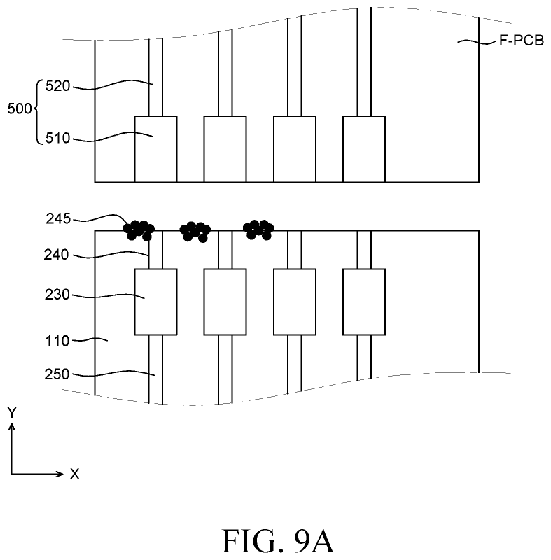

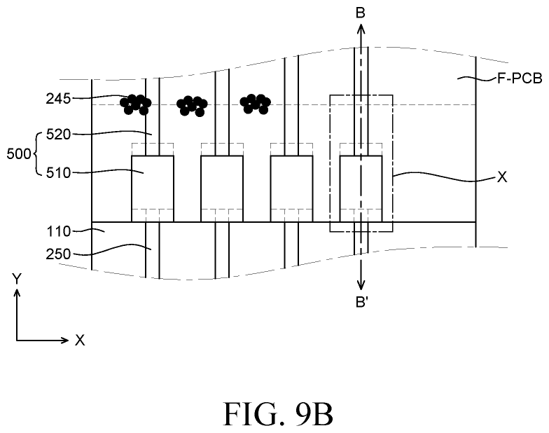

FIG. 9A is a top plan view illustrating a structure made before the first and second pads in FIG. 8 are bonded according to another embodiment of the present specification.

FIG. 9B is a top plan view illustrating a structure made after the first and second pads in FIG. 8 are bonded according to another embodiment of the present specification.

With reference to FIGS. 8A and 9A, the display panel of the display device according to the embodiment of the present specification may include the first line 240 connected to the first pad 230 and the first pad 230. The second pad 500 corresponding to the first line 240, the first pad 230, and the first pad 230 may include a body portion (second sub-pad) 510 and an extension portion (first sub-pad) 520.

The first pad 230 according to the embodiment of the present specification may have four sides. However, the present specification is not limited thereto. For example, the first pad 230 may include a fourth side 237 at one side disposed adjacent to a cut portion of the display panel 110, a first side 231 at the other side disposed adjacent to the display area AA, and a second side 233 and a third side 235 that connect two opposite sides of the first side 231 and the fourth side 237.

A length (or a width of the first pad) W4 of the first side 231 of the first pad 230 may be equal to a length of the fourth side 237. However, the present specification is not limited thereto. A length of the second side 233 of the first pad 230 may be equal to a length of the third side 235. However, the present specification is not limited thereto.

The first line 240 may have four sides. However, the present specification is not limited thereto. For example, the first line 240 may include a first side 241 at one side disposed adjacent to the first pad 230, a second side 243 at the other side disposed adjacent to the cut portion of the display panel 110, and sides that connect two opposite sides of the first side 241 and the second side 243.

A length (or a width of the test signal line) W3 of the first side 241 of the first line 240 may be equal to a length of the second side 243. However, the present specification is not limited thereto.

At the time of removing the test pad area NA-TP from the display panel 110 by the cutting process, the plurality of first lines 240 may also be cut, and the residue 245 of the first line 240 may be disposed on a lateral portion and a cross-sectional portion of the display panel 110. The connection between the lines caused by the residue 245 may be reduced by increasing distances between the plurality of first lines 240 to reduce a short circuit that occurs when some of the plurality of first lines 240 are connected to one another by the residue 245.

To increase the area in which the first pad 230 is joined (bonded) to the second pad 500, the width W3 of the first pad 230 or the length of the second side 233 may be increased. To meet the requirements related to the first pad 230 and the first line 240, the length W3 of the first side 241 of the first line 240 may be shorter than the length W4 of the first side 231 of the first pad 230. However, the embodiments of the present specification are not limited thereto.

The second pad 500 may be disposed on the rear surface of the flexible circuit board F-PCB of the display device according to the embodiment of the present specification. The second pad 500 may include the body portion (or the second sub-pad) 510 and the extension portion (or the first sub-pad) 520. The second pad 500 may be electrically connected to the first pad 230 and transmit a data driving signal from the flexible circuit board F-PCB to the display panel 110.

The second sub-pad 510 of the second pad 500 may have a plurality of sides. However, the present specification is not limited thereto. For example, the plurality of sides may include first to fourth sides. However, the embodiments of the present specification are not limited thereto. For example, the second sub-pad 510 may include a first side 511 at one side disposed adjacent to the display area AA, a fourth side 517 at the other side disposed adjacent to the source driver integrated circuit SD-IC, and a second side 513 and a third side 515 that connect two opposite sides of the first side 511 and the fourth side 517.

A length (or a width of the body portion of the second pad) W2 of the first side 511 of the second sub-pad 510 may be equal to a length of the fourth side 517. However, the present specification is not limited thereto. A length of the second side 513 of the second sub-pad 510 may be equal to a length of the third side 515. However, the present specification is not limited thereto.

The first sub-pad 520 of the second pad 500 may have a plurality of sides. However, the present specification is not limited thereto. For example, the plurality of sides may include first to fourth sides. However, the embodiments of the present specification are not limited thereto. For example, the first sub-pad 520 may include a first side 521 at one side disposed adjacent to the second sub-pad 510, a second side at the other side disposed adjacent to the source driver integrated circuit, and a third side and a fourth side that connect two opposite sides of the first side 521 and the second side.

A length (or a width of the extension portion) W1 of the first side 521 of the first sub-pad 520 constant throughout the first sub-pad 520. However, the present specification is not limited thereto.

The first pad 230 and the first line 240 may be joined to each other by the bonding (or joining) process so that the second sub-pad 510 and the first sub-pad 520 of the second pad 500 correspond to each other. For example, the residue 245 disposed on the lateral portion and the cross-sectional portion of the display panel 110 may connect some of the plurality of first sub-pads 520, which may cause a short circuit.

The connection between the lines caused by the residue 245 may be reduced by increasing distances between the plurality of first sub-pads 520 to reduce a short circuit that occurs when some of the plurality of first sub-pads 520 are connected to one another by the residue 245.

The width W1 of the first sub-pad 520 may be smaller than the width W2 of the second sub-pad 510 to reduce a short circuit that occurs when some of the plurality of first sub-pads 520 are connected to one another by the residue 245. For example, the width W1 of each of the first sub-pads 520 may vary depending on a disposition position or a shape of the residue 245. For example, according to a result of analyzing data of a manufactured prototype, the width W1 of each of the first sub-pads 520 may be 50% or less of the width W2 of each of the second sub-pads 510.

To increase the area in which the second sub-pad 510 of the second pad 500 is joined (bonded) to the first pad 230, the width W1 of the second sub-pad 510 or the length of the second side 513 may be increased. To meet the requirements related to the second sub-pad 510 and the first sub-pad 520, the length W1 of the first side 521 of the first sub-pad 520 may be shorter than the length W2 of the first side 511 of the second sub-pad 510.

Because the length W2 of the first side 511 of the second sub-pad 510 may be longer than the length W1 of the first side 521 of the first sub-pad 520, the first side 511 of the second sub-pad 510 may have a region that does not adjoin the first side 521 of the first sub-pad 520. For example, a corner portion or corner portions may be disposed at one side or two opposite sides of the first side 521 of the first sub-pad 520.

With reference to FIG. 8A, when any one lateral side of the first sub-pad 520, which is formed in a Y direction, defines a straight line with the second side 513 of the second sub-pad 510, a first corner portion C1 may be formed at the fourth side 517 that adjoins the third side 515. For example, when any one lateral side of the first sub-pad 520, which is formed in the Y direction, defines a straight line with the third side 515 of the second sub-pad 510, a second corner portion C2 may be formed at the fourth side 517 that adjoins the second side 513. For example, when the first side 521 of the first sub-pad 520 adjoins the inside of the fourth side 517 of the second sub-pad 510, the first corner portion C1 and the second corner portion C2 may be formed at two opposite sides of the fourth side 517 that adjoins the second side 513.

The first pad 230, the first line 240, and the second line 250 of the display panel 110 may define a “+” shape. For example, the configuration in which the first pad 230 and the first line 240 of the display panel 110 are joined may have a “⊥” shape. The second sub-pad 510 and the first sub-pad 520 of the second pad 500 of the flexible circuit board F-PCB may define a “⊥” shape. However, the present specification is not limited to the shapes of the first pad 230, the first line 240, and the second line 250.

With reference to FIG. 9A, the first pad 230, the second line 250, and the first line 240 may be disposed on the upper portion of the display panel 110. The second pad 500 including the second sub-pad 510 and the first sub-pad 520 may be disposed on the rear surface of the flexible circuit board F-PCB. Because the description of the constituent elements illustrated in FIG. 9A is substantially identical to the description of the constituent elements illustrated in FIG. 7A, the description of the constituent elements illustrated in FIG. 9A will be omitted or briefly described.

With reference to FIGS. 4 and 9A, the disposition position of the first line 240 may be positioned on the gate insulation layer 320 or positioned on the same layer as the third electrode 255. However, the present specification is not limited thereto. For example, the first line 240 may be disposed between constituent element layers between the substrate 310 and the third electrode 255.

In case that the first line 240 and the third electrode 255 are positioned on the same layer, the first line 240 and the first pad 230 may be exposed together to the top surface of the display panel 110 during the bonding process. The residue 245, which is produced during the cutting process, may be disposed on one side portion and the cross-sectional portion of the display panel 110.

With reference to FIGS. 8B and 9B, during the joining (or bonding) process according to the embodiment of the present specification, the first pad 230 and the first line 240 of the display panel 110 may be joined and electrically connected to the second sub-pad 510 and the first sub-pad 520 of the second pad 500 on the rear surface of the flexible circuit board F-PCB.

The width W4 of the first pad 230 may be equal to the width W2 of the second sub-pad 510 of the second pad 500. However, the present specification is not limited thereto. The width W3 of the first line 240 may be equal to the width W1 of the first sub-pad 520 of the second pad 500. However, the present specification is not limited thereto.

A length of the first pad 230 (or the second side 233) may be equal to a length of the second sub-pad 510 (or the second side 513) of the second pad 500. However, the present specification is not limited thereto. For example, a length of the second sub-pad 510 of the second pad 500 may be longer than a length of the first pad 230 to reduce a deviation of a junction area caused by a process error.

The length W3 of the first side 241 of the first line 240 may be shorter than the length W4 of the first side 231 of the first pad 230. The length W1 of the first side 521 of the first sub-pad 520 may be shorter than the length W2 of the first side 511 of the second sub-pad 510.

To suppress a short circuit between the first lines 240 caused by the residue 245, the distance between the first lines 240 needs to increase. Therefore, the width W3 of the first line 240 may decrease. On the same principle, the distance between the first sub-pads 520 of the second pad 500 needs to increase. Therefore, the width W1 of the first sub-pad 520 may decrease.

By the correction (calibration) of the misalignment during the bonding process, the first pad 230 and the second sub-pad 510 of the second pad 500 may be disposed so that there is no disposition deviation in a first direction (or a ±X direction) or a second direction (or a ±Y direction). However, the present specification is not limited thereto. For example, when a relative position of the pad, which is joined in a state in which the misalignment caused by a process error is corrected, is changed, the first pad 230 and the second sub-pad 510 may be disposed with the disposition deviation in the second direction (or the ±Y direction).

The first side 511 of the second sub-pad 510 of the second pad 500 may be disposed to be closer to the display area AA than the first side 231 of the first pad 230 to the display area AA. For example, a second interval MA2 may be defined between the first side 511 of the second sub-pad 510 and the first side 231 of the first pad 230. The fourth side 517 of the second sub-pad 510 of the second pad 500 may be disposed to be closer to the display area AA than the fourth side 237 of the first pad 230 to the display area AA. For example, a first interval MA1 may be defined between the fourth side 517 of the second sub-pad 510 and the fourth side 237 of the first pad 230.

A size of the first interval MA1 may be equal to a size of the second interval MA2. However, the present specification is not limited thereto. For example, because the length of the first pad 230 and the length of the second sub-pad 510 of the second pad 500 may be different from each other, the size of the first interval MA1 and the size of the second interval MA2 may be different from each other. For example, the size of the first interval MA1 may be adjusted to ensure a sufficient junction area between the first pad 230 and the second pad 500. For example, the size of the first interval MA1 may be inversely proportional to the width W1 of the first sub-pad 520 to ensure a sufficient junction area between the first pad 230 and the second pad 500.

The first pad 230 and the first line 240 may define a “⊥” shape to reduce the occurrence of a short circuit between the lines caused by the residue 245 that may be produced on one side portion and the cross-sectional portion of the display panel 110 during the cutting process. The second sub-pad 510 and the first sub-pad 520 of the second pad 500, which need to be bonded (or joined) to the first pad 230 and the first line 240, may also define a “⊥” shape. Therefore, it is possible to reduce the occurrence of a short circuit between the lines caused by the residue 245 and improve reliability of the display device 100.

With reference to FIG. 8C, an additional line may be disposed on the first corner portion C1 or the second corner portion C2 of the second pad 500 and connect the second sub-pad 510 and the first sub-pad 520 of the second pad 500. The additional line, which is disposed on the first corner portion C1 or the second corner portion C2, may increase a junction (or bonding) area between the second pad 500 and the first pad 230, thereby improving conductivity between the pads.

The additional line may have a straight or curved shape. However, the present specification is not limited thereto. For example, the straight shape of the additional line may be a quadrangular shape, a triangular shape, or the like. For example, the curved shape of the additional line may be an arc shape convex or concave toward the corner portion.

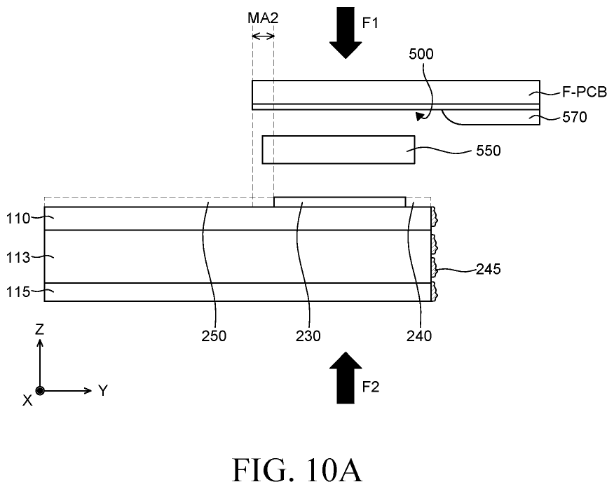

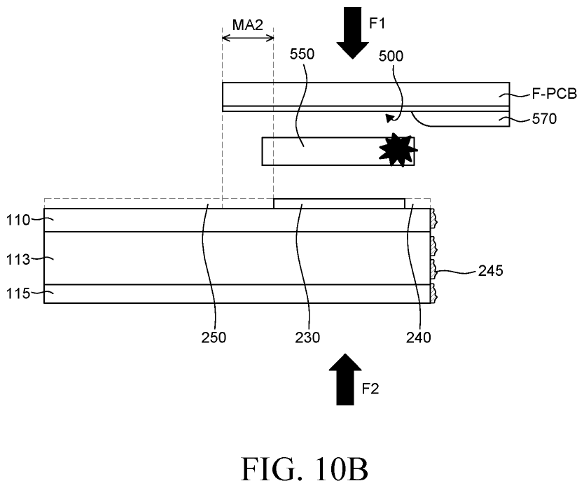

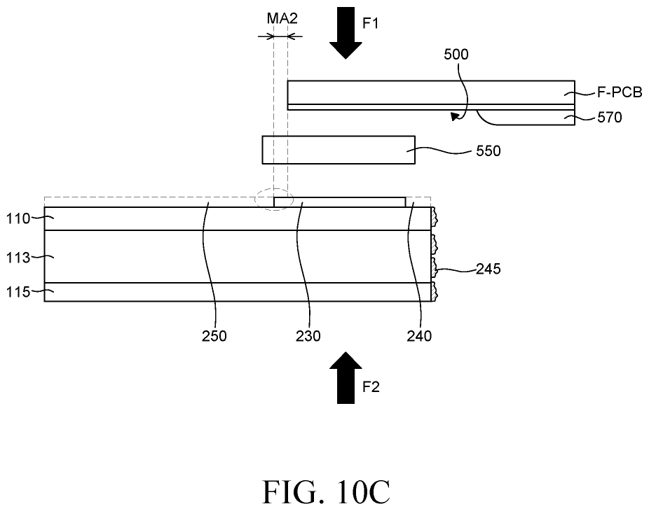

FIGS. 10A to 10C are cross-sectional views taken along cutting line B-B′ FIG. 9B according to one embodiment.

With reference to FIGS. 10A to 10C, the display device according to the embodiment of the present specification may include the display panel 110, the flexible circuit board F-PCB, and the conductive film 550 disposed between the display panel 110 and the flexible circuit board F-PCB. Because the description of the constituent elements illustrated in FIGS. 10A to 10C is substantially identical to the description of the constituent elements illustrated in FIG. 9A, the description of the constituent elements illustrated in FIGS. 10A to 10C will be omitted or briefly described.

The display panel 110 may include the first pad 230 disposed at one side, and a first member 113 and a second member 115 disposed below the display panel 110. The residue 245, which is produced during the cutting process, may be disposed on one side portion and the cross-sectional portion of the display panel 110.

The first member 113 and/or the second member 115 may each be a member that reinforces rigidity of the display panel 110. Because the display panel 110 has a small thickness, rigidity of the display panel 110 is low. For this reason, there is a risk that the display panel 110 is damaged when a force or impact is applied to the display panel 110 during a subsequent process. To eliminate the risk, the first member 113 and/or the second member 115 may be disposed below the display panel 110 to reinforce rigidity of the display panel 110.

The first member 113 may be a backplate, stainless steel (SUS), or a reinforcement member. However, the present specification is not limited to the term. The second member 115 may be a protective film, a soft reinforcement member, or the like. However, the present specification is not limited to the term.

The flexible circuit board F-PCB may include the second pad 500 disposed on the rear surface thereof, and a third member 570 configured to cover a part of the second pad 500. The third member 570 may cover a part of the second pad 500 that is not joined to the first pad 230. The third member 570 may reinforce rigidity of the second pad 500 and inhibit the second pad 500 from being short-circuited or contaminated by foreign materials.

The conductive film 550 may be disposed between the display panel 110 and the flexible printed circuit board F-PCB. The conductive film 550 may be made of a bonding material containing conductive balls. However, the present specification is not limited thereto. The conductive film 550 may be disposed to be elongated in the X direction to cover the plurality of first pads 230. A height (or a length in the Y direction) of the conductive film 550 may be larger than a length of the first pad 230 (or the second side 233). For example, the height of the conductive film 550 may have a size that includes the first pad 230.

During the bonding (or joining) process, heat may be applied to allow the bonding material of the conductive film 550 to have flexibility. During the bonding process, a force F1 may be applied in the −Z direction from above the flexible circuit board F-PCB, and a force F2 may be applied in the Z direction from below the display panel 110. The first pad 230, the conductive film 550, and the second pad 500 may be joined by the forces applied toward a center in opposite directions. The first pad 230 and the second pad 500 may be electrically connected to each other by the conductive balls contained in the conductive film 550.

With reference to FIG. 10A, the first side 511 at one side of the second sub-pad 510 of the second pad 500 may be disposed to be closer to the display area AA by the second interval MA2 than the first side 231 at one side of the first pad 230 to the display area AA. A height (or a length in the Y direction) of the second pad 500 may be larger than a height (or a length in the Y direction) of the conductive film 550. For example, a height (or a length of the exposed second and first sub-pads 510 and 520) of the second pad 500 may have a size that includes the conductive film 550.

When an area of the compressed conductive film 550 increases, the conductive film 550 may be disposed in a shape that depends on the constituent elements disposed on the top and bottom surfaces of the conductive film 550. A part of the bottom surface of the conductive film 550 may cover a top surface of the first pad 230. The remaining part of the bottom surface of the conductive film 550 may adjoin the display panel 110 and the second line 250 at a lower side (or in the −Y direction) of the first pad 230 or adjoin the display panel 110 and the first line 240 at an upper side (or in the +Y direction) of the first pad 230. A part of the top surface of the conductive film 550 may cover a rear surface of the second pad 500. The remaining part of the top surface of the conductive film 550 may adjoin a side surface of the flexible circuit board F-PCB at a lower side (or in the −Y direction) of the second pad 500 or adjoin the third member 570 at an upper side (or in the +Y direction) of the second pad 500.

With reference to FIG. 10B, in case that the second interval MA2 between the first side 511 at one side of the second sub-pad 510 of the second pad 500 and the first side 231 at one side of the first pad 230 is larger than a predetermined value in FIG. 10A, the third member 570 may move in a direction of the display area AA. For example, a part of the third member 570 is interposed in the junction region between the first pad 230 and the second pad 500, and the conductive balls in the conductive film 550 may not electrically connect the first pad 230 and the second pad 500. For this reason, a signal applied to the display panel 110 erroneously operates, which may cause a defect of the display device 100.

With reference to FIG. 10C, the first side 231 at one side of the first pad 230 may be disposed to be closer to the display area AA than the first side 511 at one side of the second sub-pad 510 of the second pad 500 to the display area AA. For example, the predetermined second interval MA2 may have a negative value. In this case, the first pad 230 may have a region that is not joined to the second pad 500. For example, a conductive area between the first pad 230 and the second pad 500 may decrease. For example, the region of the first pad 230, which is not joined to the second pad 500, is exposed during a subsequent process, which may cause a short circuit due to foreign materials. For this reason, a signal applied to the display panel 110 erroneously operates, which may cause a defect of the display device 100.

According to the embodiment of the present specification, it is possible to reduce the misalignment that may occur during the process of bonding the first pad 230 disposed on the display panel 110 and the second pad 500 disposed on the flexible circuit board F-PCB. Further, it is possible to suppress a short circuit between the first lines 240 or between the second pads 500, during a subsequent bonding process, which may be caused by the residue 245 produced during the process cutting the outer peripheral portion of the display panel 110.

The exemplary embodiments of the present disclosure can also be described as follows:

According to an aspect of the present disclosure, there is provided a display device. The display device comprises a display panel comprising a display area and a non-display area disposed outside the display area, the display panel comprising a plurality of test signal lines and a plurality of first pads disposed in the non-display area; and a flexible circuit board comprising a plurality of second pads and a printed circuit. The plurality of second pads each comprises a body portion and an extension portion. The plurality of first pads is each connected to and overlaps each of the body portions. And, the plurality of test signal lines is each connected to and overlaps each of the extension portions.

The display device may further comprise a conductive film disposed between each of the plurality of first pads and each of the body portions and between each of the plurality of test signal lines and each of the extension portions.

One side of each of the plurality of test signal lines may extend in a direction of the display area and may be connected to one side of each of the plurality of first pads. The other side each of the plurality of test signal lines may extend in a direction of the flexible circuit board and may be connected to an outer peripheral portion of the display panel.

A cross-section of the display panel and the other side of each of the plurality of test signal lines may be exposed in the outer peripheral portion of the display panel.

Residue, which is made of the same material as the plurality of test signal lines, may be disposed on the outer peripheral portion of the display panel.

One side of each of the body portions may extend in a direction of the display panel and may be connected to an outer peripheral portion of the flexible circuit board. The other side of each of the body portions may be connected to one side of each of the extension portions.

One side of each of the body portions may be closer to the display area than the other side of each of the plurality of first pads to the display area.

The other side of each of the body portions may be closer to the display area than one side of each of the plurality of first pads to the display area.

A width of the other side each of the body portions may be larger than a width of one side of each of the extension portions. One or more corner portions may be disposed in a region in which each of the body portions and each of the extension portions adjoin each other.

The one or more corner portions may have a straight shape or a curved shape.

Each of the plurality of first pads and each of the body portions may have the same shape.

Each of the plurality of first pads and each of the body portions may have a parallelogrammatic shape or a rectangular shape.

A width of each of the plurality of first pads and a width of each of the body portions may be equal to each other.

A width of each of the extension portions and a width of each of the plurality of test signal lines may be equal to each other.

Each of the plurality of first pads may have one or more layers.

According to still another aspect of the present disclosure, there is provided a display device. The display device comprises a display panel comprising a display area and a non-display area disposed outside the display area, the display panel comprising a plurality of first pads disposed in the non-display area, and a plurality of first lines extending to an outer peripheral portion thereof from the plurality of first pads; and a flexible circuit board comprising a printed circuit and a plurality of second pads electrically connected to the first pads. The plurality of second pads each comprises a first sub-pad connected to the printed circuit, and a second sub-pad extending from the first sub-pad toward the display panel to an outer periphery of the flexible circuit board.

At least a part of the first sub-pad may overlap the first line, and at least a part of the second sub-pad may overlap the first pad.

A width of the first sub-pad may be smaller than a width of the second sub-pad.

The width of the first sub-pad may be 50% or less of the width of the second sub-pad.

An outer side of the second sub-pad, which extends to the outer periphery of the flexible circuit board, may be disposed to be closer to the display area than the plurality of first pads to the display area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

What is claimed is:

1. A display device comprising:
a display panel comprising a display area and a non-display area outside the display area, the display panel comprising a plurality of test signal lines and a plurality of first pads in the non-display area; and
a flexible circuit board comprising a plurality of second pads and a printed circuit,
wherein each of the plurality of second pads comprises a body portion and an extension portion,
wherein each of the plurality of first pads is connected to and overlaps each of a plurality of body portions, and
wherein each of the plurality of test signal lines is connected to and overlaps each of a plurality of extension portions.

2. The display device of claim 1, further comprising:
a conductive film between each of the plurality of first pads and each of the plurality of body portions and between each of the plurality of test signal lines and each of the plurality of extension portions.

3. The display device of claim 1, wherein one side of each of the plurality of test signal lines extends in a direction of the display area and is connected to one side of each of the plurality of first pads, and
wherein another side each of the plurality of test signal lines extends in a direction of the flexible circuit board and is connected to an outer peripheral portion of the display panel.

4. The display device of claim 3, wherein a cross-section of the display panel and the other side of each of the plurality of test signal lines are exposed in the outer peripheral portion of the display panel.

5. The display device of claim 4, wherein residue, which is made of a same material as the plurality of test signal lines, is on the outer peripheral portion of the display panel.

6. The display device of claim 1, wherein one side of each of the plurality of body portions extends in a direction of the display panel and is connected to an outer peripheral portion of the flexible circuit board, and
wherein another side of each of the body portions is connected to one side of each of the plurality of extension portions.

7. The display device of claim 3, wherein one side of each of the plurality of body portions is closer to the display area than the other side of each of the plurality of first pads to the display area.

8. The display device of claim 3, wherein the other side of each of the plurality of body portions is closer to the display area than one side of each of the plurality of first pads to the display area.

9. The display device of claim 6, wherein a width of the other side each of the plurality of body portions is larger than a width of one side of each of the plurality of extension portions, and
wherein one or more corner portions are in a region in which each of the plurality of body portions and each of the plurality of extension portions adjoin each other.

10. The display device of claim 9, wherein the one or more corner portions have a straight shape or a curved shape.

11. The display device of claim 1, wherein each of the plurality of first pads and each of the plurality of body portions have a same shape.

12. The display device of claim 11, wherein each of the plurality of first pads and each of the plurality of body portions have a parallelogrammatic shape or a rectangular shape.

13. The display device of claim 11, wherein a width of each of the plurality of first pads and a width of each of the plurality of body portions are equal to each other.

14. The display device of claim 1, wherein a width of each of the plurality of extension portions and a width of each of the plurality of test signal lines are equal to each other.

15. The display device of claim 1, wherein each of the plurality of first pads has one or more layers.

16. A display device comprising:
a display panel comprising a display area and a non-display area outside the display area, the display panel comprising a plurality of first pads in the non-display area, and a plurality of first lines extending to an outer peripheral portion thereof from the plurality of first pads; and
a flexible circuit board comprising a printed circuit and a plurality of second pads electrically connected to the first pads,
wherein the plurality of second pads each comprises a first sub-pad connected to the printed circuit and a second sub-pad extending from the first sub-pad toward the display panel to an outer periphery of the flexible circuit board.

17. The display device of claim 16, wherein at least a part of the first sub-pad overlaps a first line from the plurality of first lines, and at least a part of the second sub-pad overlaps a first pad from the plurality of first pads.

18. The display device of claim 17, wherein a width of the first sub-pad is smaller than a width of the second sub-pad.

19. The display device of claim 18, wherein the width of the first sub-pad is 50% or less of the width of the second sub-pad.

20. The display device of claim 16, wherein an outer side of the second sub-pad, which extends to the outer periphery of the flexible circuit board, is closer to the display area than the plurality of first pads to the display area.
